(19) United States
(12) Patent Application Publication
(10) Pub. No.: US 2015/0268273 A1
(43) Pub. Date: Sep. 24, 2015

(54) CONDUCTIVE TEST PROBE INCLUDING CONDUCTIVE, CONFORMABLE COMPONENTS

(71) Applicant: Apple Inc., Cupertino, CA (US)

(72) Inventors: Anuranjini Pragada, San Jose, CA (US); Ming L. Sartee, Morro Bay, CA (US); Shin John Choi, Sunnyvale, CA (US); Joon Kwon, San Ramon, CA (US); Richard Lim, San Jose, CA (US); Michael McCord, Mountain View, CA (US)

(73) Assignee: Apple Inc., Cupertino, CA (US)

(21) Appl. No.: 14/221,058

(22) Filed: Mar. 20, 2014

(51) Int. Cl. G01R 1/067

(52) U.S. Cl. CPC G01R 1/06783; G01R 1/067; G01R 1/06722

(57) ABSTRACT

A test probe system including a test probe structure. The test probe system may include the test probe structure including a probe support, and a conductive, conformable component coupled to the probe support. The conductive, conformable component may be configured to: directly contact a test surface of a test structure, or couple a conductive element to the probe support. The conductive element may directly contact the test surface of the test structure. The test probe system may also include a conductive liquid dispensing system coupled to the test probe structure. The conductive liquid dispensing system may be configured to supply a conductive liquid to the test surface of the test structure.

### TECHNICAL FIELD

The disclosure relates generally to material testing systems, and more particularly, to a conductive test probe including a conductive, conformable component and a method of testing a material using the conductive test probe.

### BACKGROUND

Electrical test probes may be used to test the electrical properties of a material or an electronic component of an electronic device. For example, conventional test probes are typically utilized to test the electrical conductivity of a material or a component of an electronic device. The conductivity may relate to an ability to conduct or allow electric current to pass through a material. When manufacturing electronic devices, it is important that the conductivity of the materials utilized in the electronic device are tested prior to implementation within the electronic device and/or prior to the device being provided to a user (for example, consumer). The conductivity of the materials forming the electronic components may affect the operational characteristics of the electronic components and/or the electronic device utilizing the electronic component. For example, the conductivity of the materials forming the electronic components may be affect and/or be related to, directly or indirectly, operational characteristics such as: the operational life of the electronic component/device, the operational response time for the electronic component, and the current generated/required by the electronic component to function as desired.

Typically, conventional test probes include a conductive component positioned at the end of an armature or frame, where the contact component may contact a surface of a test material or component. That is, the contact component of the test probe may contact the surface of the test material or component to determine the conductivity of the contacted test material or component. The test probe may determine the conductivity of the test material or component by including a conventional measuring system in electronic communication with the contact component. For example, the conventional measuring system may provide an electric current to the test material or component via the contact component, and may determine the test material or component's capacity to accept the current and/or the ability to resist the current.

As result of the methods for testing conductivity using a conventional test probe, the contact component typically includes a conductive material. Conventional contact components often include thick, flat plates formed from metals having electrically conductive properties. The electrically conductive properties of the metal plates used in the contact component allow conventional test probes to get accurate readings when an ideal surface contact between the contact component and the test material or component is achieved. That is, when the metal plate forming the contact component completely contacts (for example, seamless contact) the surface of the test material or component, the test probe may accurately determine the conductivity of the test material or component. The ideal surface contact between the contact component and the test material or component may allow the measuring device to provide a desired electric current to test material or component and subsequently receive the maximum amount of input based on the seamless surface contact.

However, due to the rigid or inelastic properties of the metal plate of the contact component, an ideal surface contact may only be formed between the contact component and the surface of the test material or component where the surface of the test material or component is substantially flat or planer. When the test material or component includes a substantially non-planer surface, conventional test probes may not get accurate readings. More specifically, when the test material or component includes a non-planer surface, the contact component may not conform to the non-planer surface of the test material or component, and may not form an ideal surface contact with the test material or component. Rather, gaps or disconnects may be present between the contact component of the test probe and the surface of the test material or component. As a result, the electric current provided during conductivity testing may not be completely received by the test material or component as a result of the gaps or disconnects between the contact component and the test material or component. This may ultimately skew the conductivity results determined by the measuring system.

Contact components of conventional test probes may be manufactured to include configurations or shapes that correspond to non-planer surfaces. However, these custom contact components may be expensive to manufacture and/or may only correspond to a specific test material or component. As a result, a plurality of custom contact components may be required when testing a single device that may include a plurality of components. Additionally, when the surface of the test material or component varies slightly as a result of variations in the manufacturing process, the custom contact components may still fail in providing an ideal surface contact as a result of the contact components' inability to conform to the slight surface variation.

### SUMMARY

Generally, embodiments discussed herein are related to a test probe structure, a test probe system including a test probe structure, and a method for testing a structure using a test probe system including a test probe structure. The test probe structure may include a conductive conformable component. The conductive conformable component may include a conductive material having substantially elastic or flexible properties to allow the test probe structure to form an ideal or maximum surface contact (for example, seamless) with a test surface. That is, the conductive conformable component may form a maximum surface contact with a test surface, having a planer or non-planer surface, as a result of the conductive conformable component's ability to contour around the test surface of the test structure. Additionally, the test probe system including the test probe structure may also include a conductive liquid dispensing system. The conductive liquid dispensing system may dispense a conductive liquid on the test surface of the test structure, prior to the test probe structure contacting and determining the conductivity of the test structure. The conductive liquid may also aid in forming a maximum surface contact between the test probe structure and the test surface of the test structure. More specifically, the conductive liquid may form a continuous, conductive film between the test probe structure and the test surface to provide a seamless electrical contact during the conductivity testing process.

One embodiment may include a test probe structure. The test probe structure may include a probe support, and a conductive, conformable component coupled to the probe support. The conductive, conformable component may be configured to: directly contact a test surface of a test structure, or couple a conductive element to the probe support. The conductive element may directly contact the test surface of the test structure.

Another embodiment may include a test probe system. The test probe system may include a test probe structure including a probe support, and a conductive, conformable component coupled to the probe support. The conductive, conformable component may be configured to: directly contact a test surface of a test structure, or couple a conductive element to the probe support. The conductive element may directly contact the test surface of the test structure. The test probe system may also include a conductive liquid dispensing system coupled to the test probe structure. The conductive liquid dispensing system may be configured to supply a conductive liquid to the test surface of the test structure.

A further embodiment may include a method of testing a structure. The method may include providing a test probe structure including: a conductive, conformable component configured to: directly contact a surface of the structure, or couple a conductive element to a probe support of the test probe structure. The conductive element may directly contact the surface of the structure. The method may also include dispensing a conductive liquid on the surface of the structure, and adjusting the test probe structure to contact the conductive liquid dispensed on the surface of the structure. Additionally, the method may include determining the conductivity of the test structure using the test probe structure in contact with the conductive liquid dispensed on the surface of the structure.

### BRIEF DESCRIPTION OF THE DRAWINGS

The disclosure will be readily understood by the following detailed description in conjunction with the accompanying drawings, wherein like reference numerals designate like structural elements, and in which:

FIG. 1A shows a perspective view of a test probe structure including a conductive, conformable component, according to embodiments.

FIGS. 1B and 1C show cross-sectional front views of the test probe structure shown in FIG. 1A, according to embodiments.

FIGS. 2A-5C shows perspective, and front cross-sectional views of test probe structures including conductive, conformable components, according to alternative embodiments.

FIG. 6 shows an illustrative view of a test probe system including a test probe structure and a conductive liquid dispensing system, according to embodiments.

FIG. 7 shows a flow chart illustrating a method for testing conductivity of a test structure. This method may be performed using the test probe system as shown in FIG. 6.

FIGS. 8A-8C show illustrative views of a test probe system, including a test probe structure and a conductive liquid dispensing system, undergoing processes of testing conductivity as depicted in FIG. 7, according to embodiments.

It is noted that the drawings of the invention are not necessarily to scale. The drawings are intended to depict only typical aspects of the invention, and therefore should not be considered as limiting the scope of the invention. In the drawings, like numbering represents like elements between the drawings.

### DETAILED DESCRIPTION

Reference will now be made in detail to representative embodiments illustrated in the accompanying drawings. It should be understood that the following descriptions are not intended to limit the embodiments to one preferred embodiment. To the contrary, it is intended to cover alternatives, modifications, and equivalents as can be included within the spirit and scope of the described embodiments as defined by the appended claims.

The following disclosure relates generally to material testing systems, and more particularly, to a conductive test probe including a conductive, conformable component and a method of testing a material using the conductive test probe.

In a particular embodiment, the test probe structure may include a conductive conformable component. The conductive conformable component may include a conductive material having substantially elastic or flexible properties to allow the test probe structure to form an ideal or maximum surface contact (for example, seamless) with a test surface. That is, the conductive conformable component may form a maximum surface contact with a test surface, having a planer or non-planer surface, as a result of the conductive conformable component's ability to contour around the test surface of the test structure.

Additionally, the test probe system including the test probe structure may also include a conductive liquid dispensing system. The conductive liquid dispensing system may dispense a conductive liquid on the test surface of the test structure, prior to the test probe structure contacting and determining the conductivity of the test structure. The conductive liquid may also aid in forming a maximum surface contact between the test probe structure and the test surface of the test structure. More specifically, the conductive liquid may form a continuous, conductive film between the test probe structure and the test surface to provide a seamless electrical contact during the conductivity testing process.

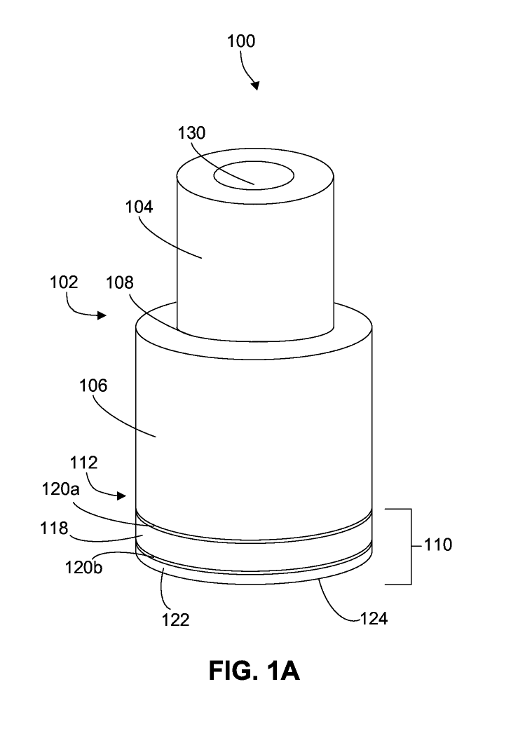

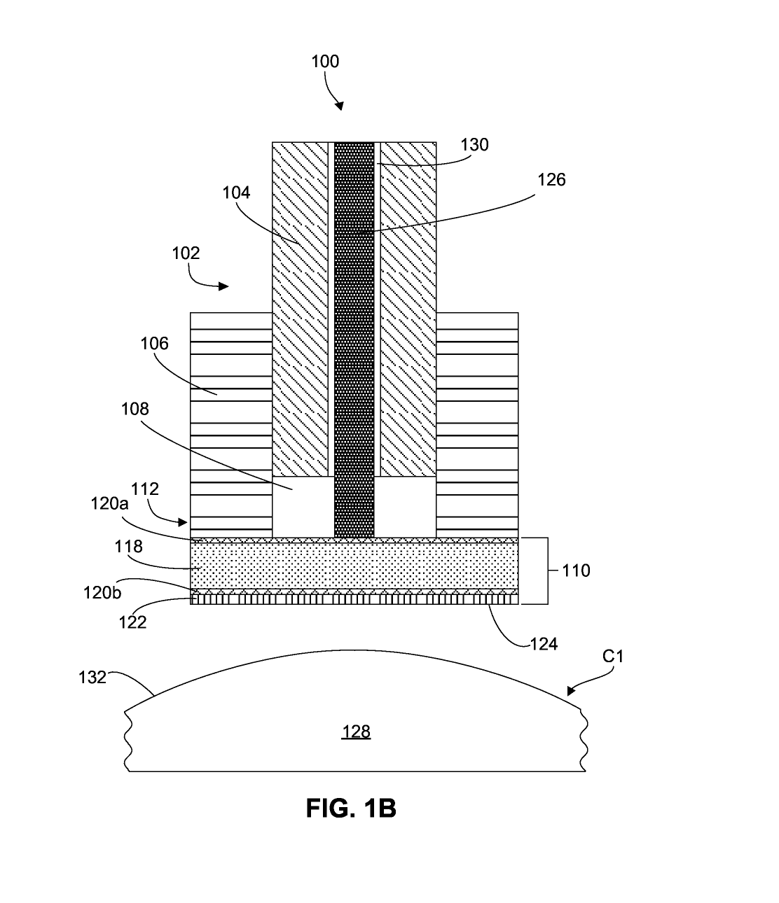

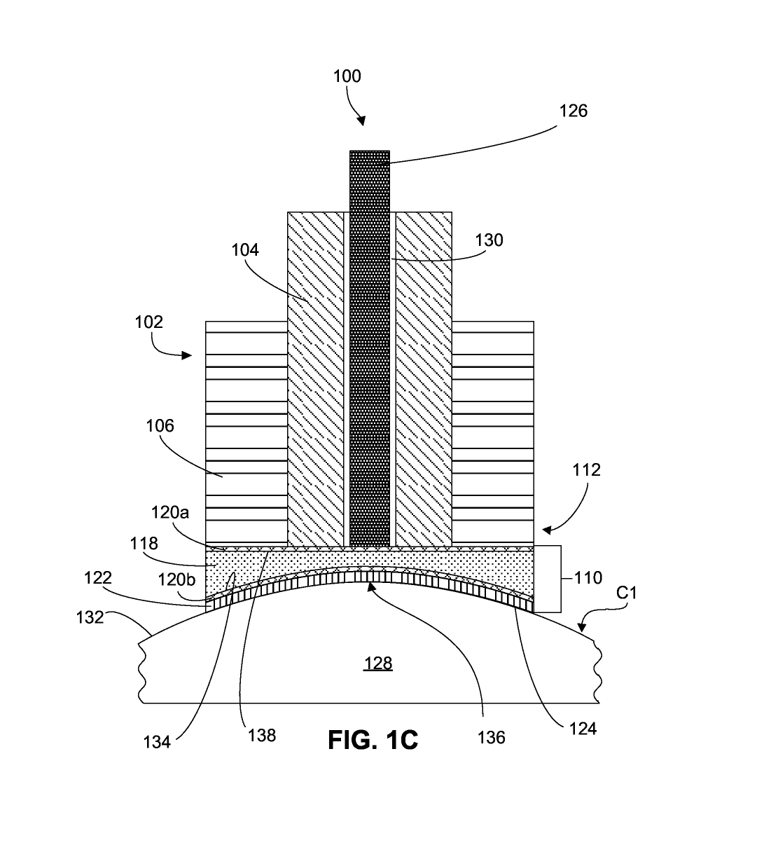

These and other embodiments are discussed below with reference to FIGS. 1A-8C. However, those skilled in the art will readily appreciate that the detailed description given herein with respect to these Figures is for explanatory purposes only and should not be construed as limiting.

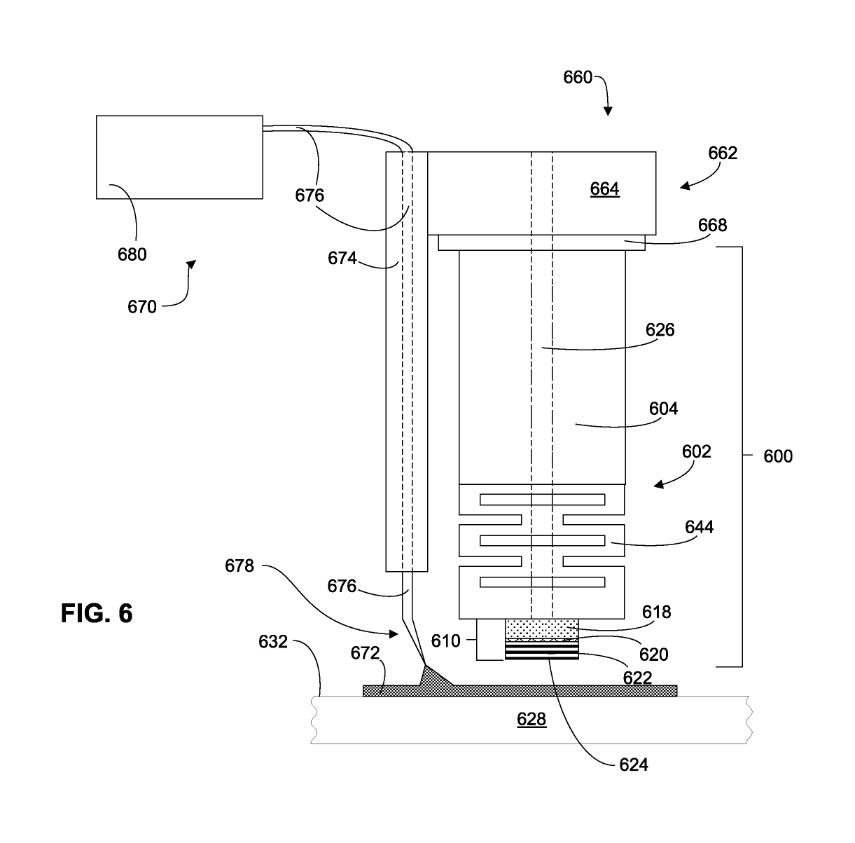

FIG. 1A, shows a perspective view of one example of a portion of test probe structure including a conductive, conformable component. In the illustrated embodiment, the portion of the test probe structure 100 may include a probe support 102. Probe support 102, as shown in FIG. 1A may include a probe shaft 104 and a probe housing 106 configured to receive probe shaft 104. Probe shaft 104 may be concentrically positioned within an opening 108 of probe housing 106, and may be slidingly coupled to probe housing 106 and configured to move vertically within opening 108 of probe housing 106. As shown in FIG. 1A, probe housing 106 may substantially surround a portion of probe shaft 104 of probe support 102 to prevent probe shaft 104 and its internal components from being exposed. As discussed herein, probe shaft 104 may be coupled to an armature of a test probe system (see, FIG. 6) that may control or move probe support 102 of test probe structure 100 during the conductivity testing of a test structure.

As discussed herein, the material(s) utilized to form probe support 102 may be dependent, at least in part, on the configuration of test probe structure 100. That is, probe shaft 104 and/or probe housing 106 may be made from a plurality of material(s), wherein the material(s) may be dependent, at least in part, on the configuration of the contact portion 110 of test probe structure 100. As shown in FIG. 1A, probe shaft 104 and probe housing 106 may be made from any conventional material that may support contact portion 110 of test probe structure 100, and may be structurally-sound during the conductivity testing, as discussed herein. In a non-limiting example, probe shaft 104 and/or probe housing 106 of probe support 102 may be formed from: polymer, metal, composite materials, ceramics or any combination.

As shown in FIG. 1A, contact portion 110 of test probe structure 100 may be coupled to a first end 112 of probe support 102. As discussed herein, first end 112, including contact portion 110, of test probe structure 100 may be positioned substantially adjacent to a test surface of a test structure (see, FIGS. 1B and 1C) to allow contact portion 110 of test probe structure 100 to contact the test surface during a conductivity testing process.

Contact portion 110 of test probe structure 100 may include a plurality of components. As shown in FIG. 1A, contact portion 110 of test probe structure 100 may include a conductive, conformable component 118 coupled to probe support 102. More specifically, contact portion 110 may include conductive, conformable component 118 coupled to first end 112 of probe support 102. Conductive, conformable component 118 may be coupled to probe shaft 104 and/or probe housing 106, dependent, at least in part, on the configuration of probe shaft 104 and probe housing 106 of probe support 102. In a non-limiting example, conductive, conformable component 118 may be coupled to probe housing 106 at first end 112 of probe support 102, where probe shaft 104 may be slidingly coupled and configured to move within probe housing 106, as discussed herein.

Conductive, conformable component 118 of test probe structure 100 may include a variety of materials that may include conformable, elastic and/or flexible physical characteristics, as well as, electrically conductive characteristics. That is, conductive, conformable component 118 may include a material that is both conformable under pressure and provides an electrically conductive layer during the conductivity testing of the test structure, as discussed herein. In non-limiting examples, conductive, conformable component 118 may include at least one of: electrically conductive foams, electrically conductive polymers, electrically conductive fabric material, or any combination thereof.

As shown in FIG. 1A, conductive, conformable component 118 may be coupled to probe support 102 using a conductive adhesive 120a. That is, test probe structure 100 may include conductive adhesive 120a positioned between conductive, conformable component 118 and probe support 102 for coupling conductive, conformable component 118 to probe housing 106. Conductive adhesive 120a may include any adhesive material, having electrically conductive properties that may couple conductive, conformable component 118 to probe support 102. However, it is understood that additional conductive coupling techniques or materials may be used to couple conductive, conformable component 118 to probe support 102 of test probe structure 100. In a non-limiting example, an electrically conductive tape may be used to couple conductive, conformable component 118 to probe support 102. In an additional embodiment, conductive, conformable component 118 may be coupled to probe support 102 using a soldering technique, such that an electrically conductive layer (for example, solder) may be positioned between and couple conductive, conformable component 118 to probe support 102.

Contact portion 110 of test probe structure 100 may also include a conductive element 122 coupled to conductive, conformable component 118 using conductive adhesive 120b. As similarly discussed with respect to probe support 102 and conductive, conformable component 118, conductive adhesive 120b may be positioned between conductive element 122 and conductive, conformable component 118 may be configured to couple conductive element 122 to conductive, conformable component 118, and indirectly to probe support 102 of test probe structure 100. As shown in FIG. 1A, conductive, conformable component 118 may be an intermediate conductive layer of contact portion 110 that may aid in coupling conductive element 122 to probe support 102 of test probe structure 100.

As shown in FIG. 1A, conductive element 122 may also include a contact surface 124 positioned opposite conductive, conformable component 118. That is, conductive element 122 of test probe structure 100 may include an exposed contact surface 124 positioned adjacent to conductive, conformable component 118 and probe support 102. As discussed herein, contact surface 124 may contact and form a maximum surface contact (for example, seamless contact) with a test surface of a test structure (see, FIGS. 1B and 1C) during a conductivity testing process.

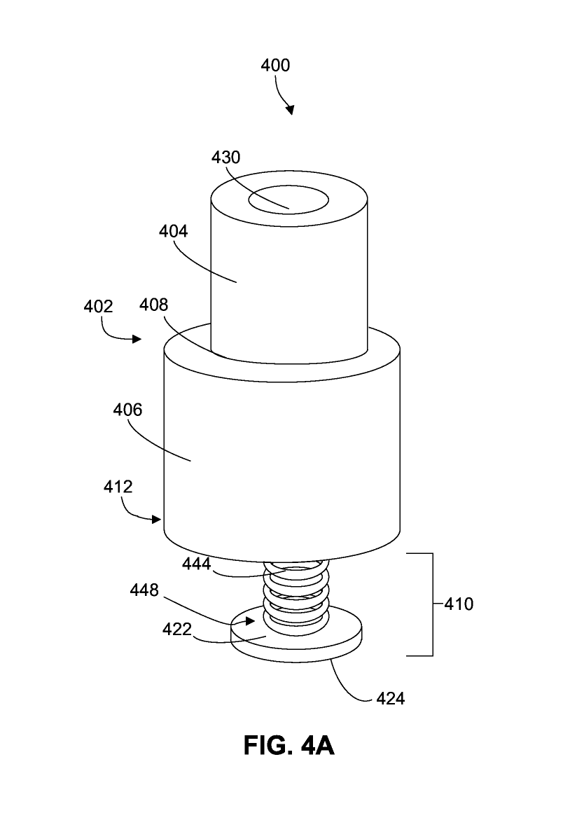

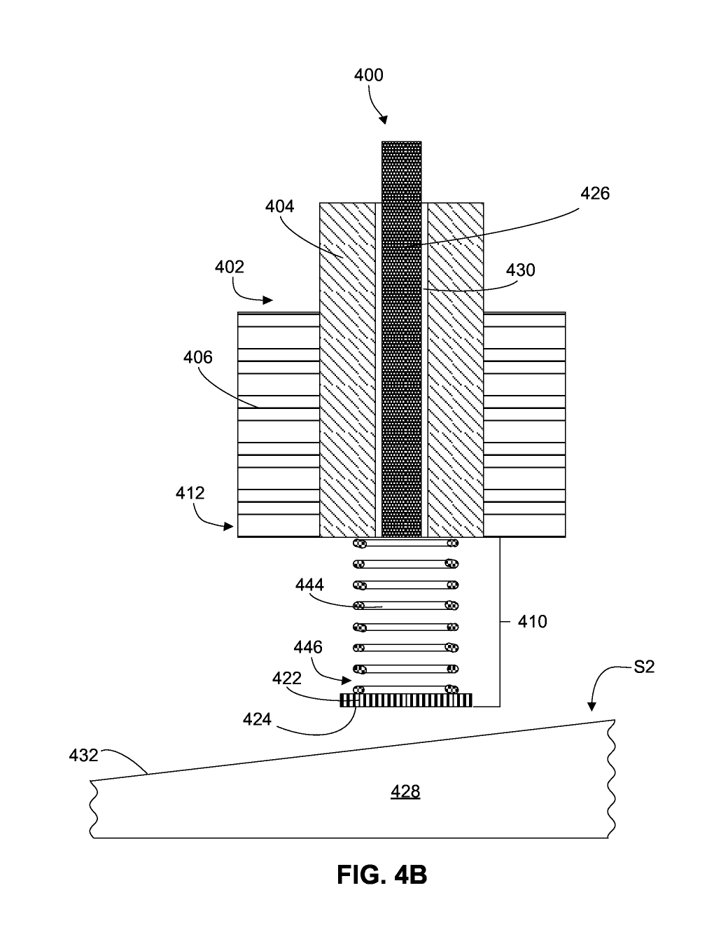

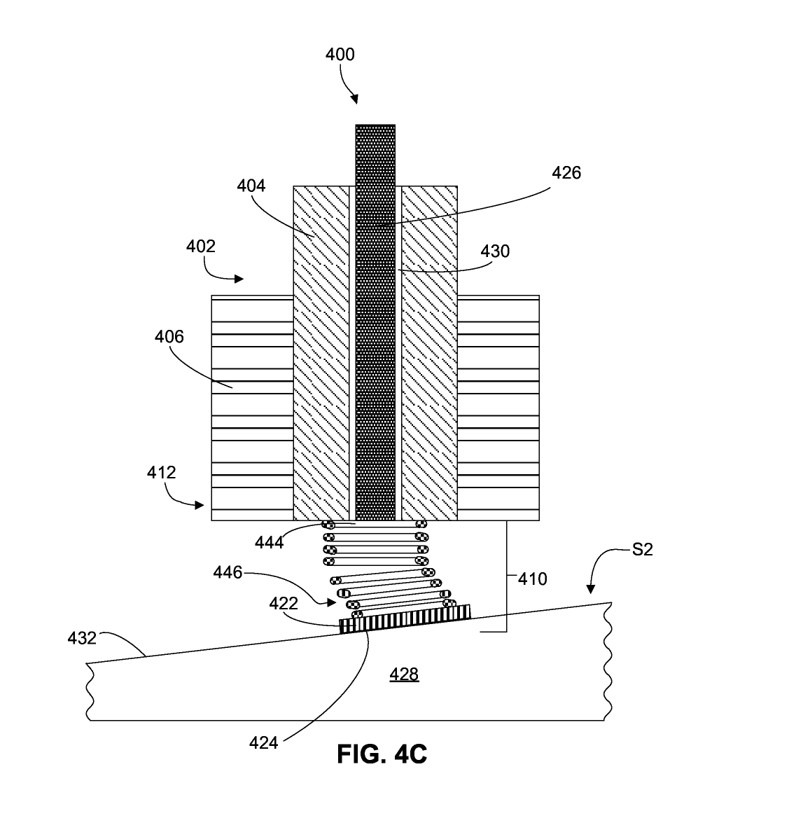

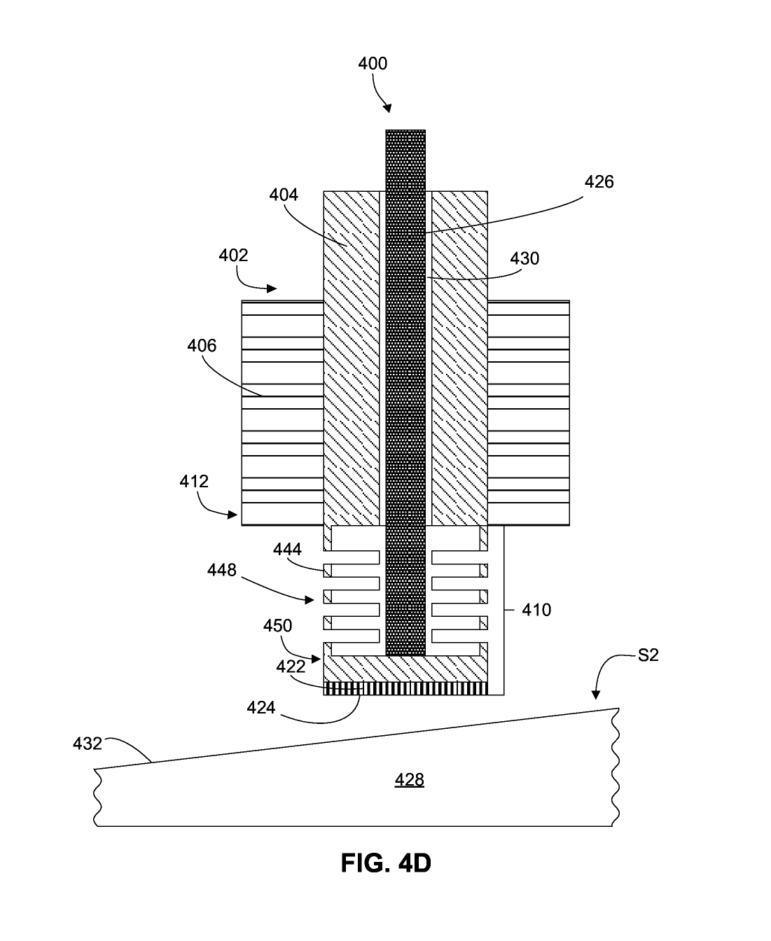

Conductive element 122 of test probe structure 100 may include one of a substantially flexible conductive film, or a substantially rigid conductive plate. In a non-limiting example, as shown in FIG. 1A, conductive element 122 may include a substantially flexible conductive film, that may be both electrically conductive and elastic or flexible. As discussed herein, when conductive element 122 includes a substantially flexible conductive film, conductive element 122 may conform or bend with conductive, conformable component 118 to form an ideal or maximum surface contact with a test surface of a test structure (see, FIGS. 1B and 1C). Additionally as discussed herein, when conductive element 122 includes a substantially rigid plate, conductive, conformable component 118 may be configured to conform or bend, while conductive element 122 remains substantially rigid, to form an ideal or maximum surface contact with a test surface of a test structure (see, FIGS. 4B and 4C).

FIG. 1B shows a cross-sectional front view of test probe structure 100 of FIG. 1A positioned above a test structure according to embodiments. As shown in FIG. 1B, test probe structure 100 may also include a wire 126 in electronic communication with contact portion 110 of test probe structure 100. More specifically, wire 126 may be electrically coupled to conductive element 122 of contact portion 110, and may be configured to provide test structure 128 with an electrical current, via contact portion 110, during a conductivity testing process, as discussed herein. As shown in FIG. 1B, wire 126 may be positioned within an opening 130 formed through probe shaft 104 of probe support 102, and may electrically couple contact portion 110 of test probe structure 100 to a conductivity measuring system (not shown) utilized during the conductivity testing process. In a non-limiting example, wire 126 may be coupled directly to and in direct electronic communication with conductive element 122. In another non-limiting example, wire 126 may be coupled to a distinct portion (e.g., conductive, conformable component 118, adhesive layer 120) of contact portion 110 of test probe structure 100. As a result of coupling wire 126 to a distinct portion of contact portion 110, wire may be in indirect electronic communication with conductive element 122 via the plurality of other components of contact portion 110. That is, because each layer or component of contact portion 110 of test probe structure 102 is electrically conductive, wire 126 may be indirectly coupled to conductive element 122 via the various conductive components forming contact portion 110. In a further non-limiting example, wire 126 may only be positioned within probe shaft 104, and may not always be in electronic communication with contact portion 110. That is, wire 126 may only be in electronic communication with contact portion 110 of test probe structure 100 when conductive element 122 of contact portion 110 contacts test structure 128 and probe shaft 104 moves toward and/or contacts contact portion 110, as discussed herein.

As shown in FIG. 1B, test structure 128 may include any material, or a portion of a conductive material used within an electronic component that may undergo a conductivity testing process, as discussed herein. In an non-limiting example, test structure 128 may be a portion of a conductive material included within a touch sensor circuitry for an electronic device (not shown) including interactive touch capabilities. In an additional, non-limiting example, test structure 128 may include a portion of a synthetic conductive material that may be utilized within an electronic component. A conductivity testing process, as discussed herein, may be performed on the synthetic conductive material to determine if the synthetic conductive material includes a desired electric conductivity, prior to being utilized within the electronic component.

Test structure 128 may include a test surface 132. Test surface 132 of test structure 128 may include an exposed surface of test structure 128 that may be configured to contact test probe structure 100 during a conductivity testing process, as discussed herein. Test surface 132 of test structure 128 may include a planer surface or a non-planer surface. In a non-limiting example, as shown in FIG. 1B, test surface 132 may include a substantially non-planer, convex curvature (C1). The substantially convex curvature (C1) of test surface 132 may be formed on test structure 128 as a result of a variety of factors including, but not limited to: manufacturing techniques for forming test structure 128, compositional/physical properties of test structure 128, implementation of test structure 128 within additional embodiments, etc.

FIG. 1C shows the cross-sectional front view of test probe structure 100 of FIG. 1B contacting test structure 128 according to embodiments. As shown in FIG. 1C, contact portion 110 of test probe structure 100 may contact test surface 132 of test structure 128. That is exposed contact surface 124 of conductive element 122 may directly contact test surface 132 of test structure 128. By contacting conductive element 122 of contact portion 110 to test structure 128, the various components or layers forming contact portion 110 of test probe structure 100 may conform and/or flex as a result of each components flexible or elastic characteristics. As discussed in detail below, test probe structure 100, and specifically contact portion 110, may contact test surface 132 of test structure 128 during the conductivity testing process.

As a result of contact portion 110 contacting test structure 128, at least a portion of the various components or layers forming contact portion 110 may include curvatures similar to the convex curvature (C1) of test surface 132. As shown in FIG. 1C, and with comparison to FIG. 1B, both conductive element 122 and adhesive layer 120b, may include a substantially convex curvature that may correspond or compliment convex curvature (C1) of test surface 132 when contact portion 110 of test probe structure 100 contacts test structure 128. Additionally, conductive element 122 and adhesive layer 120b may maintain a uniform thickness, and may not be substantially compressed when contact portion 110 of test probe structure 100 contacts test structure 128.

As shown in FIG. 1C, conductive, conformable component 118 may also include a substantially convex curvature that may correspond or compliment convex curvature (C1) of test surface 132 when contact portion 110 of test probe structure 100 contacts test structure 128. More specifically, as shown in FIG. 1C, conductive, conformable component 118 may include a first surface 134 that is coupled to adhesive layer 120b and includes a curvature that corresponds to the convex curvature (C1) of test surface 132 when contact portion 110 contacts test structure 128. However, distinct from conductive element 122 and adhesive layer 120b, conductive, conformable component 118 may not maintain a uniform thickness when contact portion 110 contacts test structure 128. That is, as shown in FIG. 1C, and as compared to FIG. 1B, conductive, conformable component 118 may be substantially compressed when contact portion 110 contacts test structure 128, which may result in a change in thickness of conductive, conformable component 118. More specifically, the thickness of conductive, conformable component 118 at a peak 136 of test surface 132 of test structure 128 may be substantially smaller than the thickness of a portion of conductive, conformable component 118 positioned opposite peak 136. As a result of the change in thickness between conductive, conformable component 118, conductive, conformable component 118 may include a second surface 138 coupled to conductive adhesive 120a that may not include a curvature. That is, because conductive, conformable component 118 may be compressed and may include a change in thickness, the orientation of second surface 138 of conductive, conformable component 118 may be substantially unchanged when contact portion 110 of test probe structure contacts test structure 128. Additionally, because conductive, conformable component 118 is compressed and the orientation of second surface 138 remains substantially unchanged, conductive adhesive 120a may also remain unchanged. That is, the orientation of conductive adhesive 120a may be unchanged, and/or may not include a curvature corresponding or complementing convex curvature (C1) of test surface 132 when contact portion 110 contacts test structure 128.

By including various conformable and conductive components or layers in contact portion 110 of test probe structure 100, contact portion 110 of test probe structure 100 may be able to obtain an ideal or maximum surface contact with test structure 128 that includes a non-planer test surface 132. That is, as shown in FIG. 1C and discussed above, contact portion 110 and at least a portion of the various components or layers forming contact portion 110, may conform to include a corresponding or complementary curvature to convex curvature (C1) of test surface 132. By including conformable components or layers (e.g., conductive, conformable component 118) that may form a complementary curvature to test surface 132, contact portion 110 of test probe structure 100 may form a maximum surface contact with test structure 128 during a conductivity testing process, such that no spaces or openings may be formed between conductive element 122 and test surface 132 of test structure 128.

Additionally shown in FIG. 1C, and with comparison to FIG. 1B, probe shaft 104 may slidingly move within probe housing 106, toward test structure 128 when contacting contact portion 110 with test structure 128. More specifically, probe shaft 104 may slidingly move within probe housing 106 to apply an additional force on probe housing 106 and/or contact portion 110 coupled to probe housing 106 of probe support 102. The force applied by probe shaft 104 may ensure that contact portion 110, and at least a portion of the various components or layers forming contact portion 110, conform to include a corresponding or complementary curvature to the convex curvature (C1) of test surface 132 of test structure 128. As discussed herein, the conforming of contact portion 110, and at least a portion of the various components or layers forming contact portion 110, may provide maximum contact surface between conductive element 122 of test probe structure 100 and test structure 128 during a conductivity testing process.

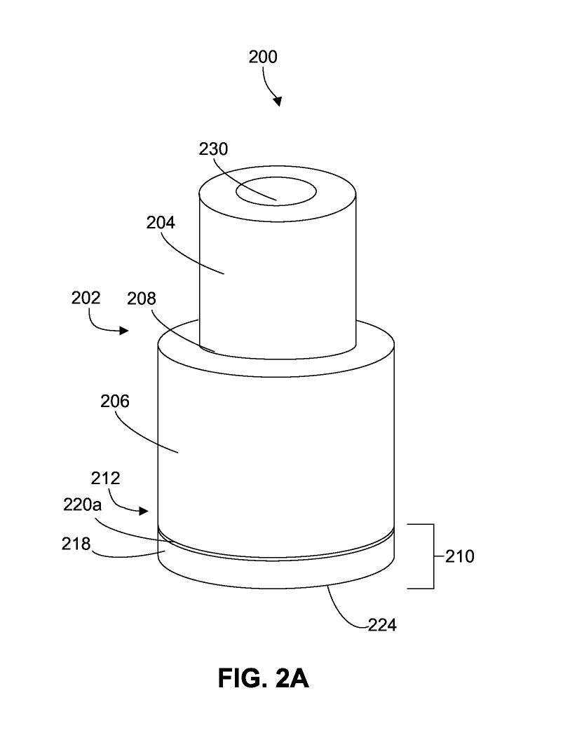

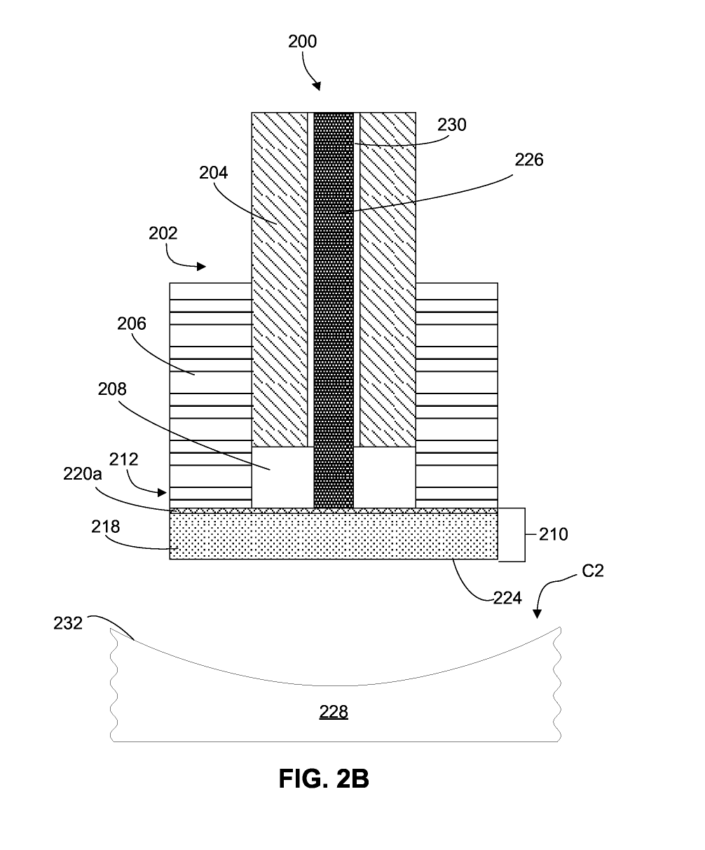

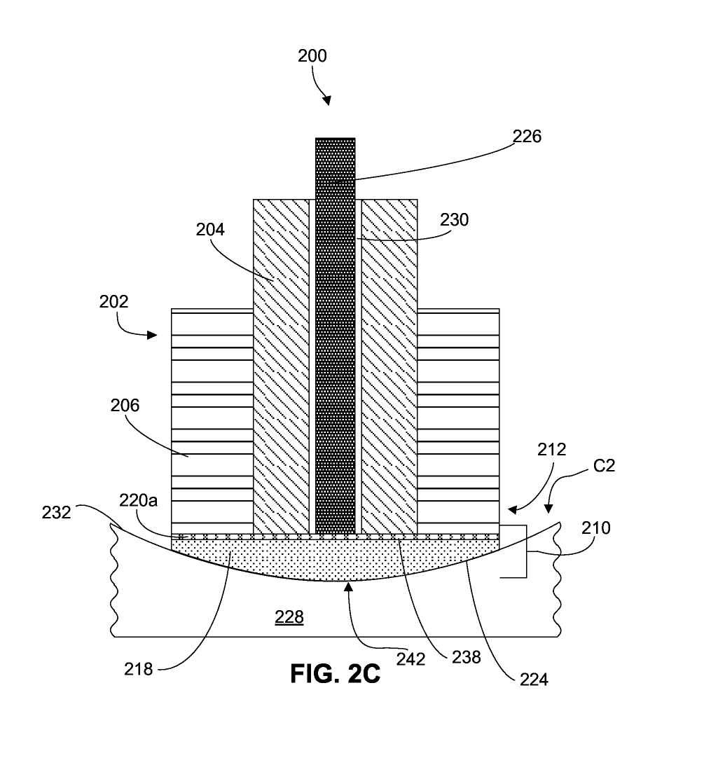

FIG. 2A shows a perspective view of test probe structure 200 according to an alternative embodiment. Test probe structure 200 may include substantially similar components (e.g., probe shaft 104, probe housing 106, etc.) as test probe structure 100. It is understood that similarly named components or similarly numbered components may function in a substantially similar fashion, may include similar materials and/or may include similar interactions with other components. Redundant explanation of these components has been omitted for clarity.

As shown in FIG. 2A, test probe structure 200 may include contact portion 210. With comparison to FIG. 1A, contact portion 210 of test probe structure 200 of FIG. 2A may include a distinct or unique configuration. More specifically, contact portion 210 may include a conductive, conformable component 218 coupled to probe support 202 of test probe structure 200. As similarly discussed herein with respect to FIG. 1A, conductive, conformable component 218 may be coupled to probe housing 206 via conductive adhesive 220a. With comparison to contact portion 110 of test probe structure 100 in FIG. 1A, contact portion 210 of test probe structure 200, as shown in FIG. 2A, may only include conductive, conformable component 218 and conductive adhesive 220a. As such, contact surface 224 of contact portion 210 may be a bottom surface of conductive, conformable component 218. That is, conductive, conformable component 218 of contact portion 210 of test probe structure 200 may include contact surface 224, configured to directly contact test surface 232 of test structure 228 (see, FIGS. 2B and 2C) during a conductivity testing process, as discussed herein.

FIGS. 2B and 2C shows a cross-sectional front view of test probe structure 200 of FIG. 2A positioned above test structure 228 according to embodiments. As shown in FIGS. 2B and 2C, test structure 228 may include a distinct configuration or shape when compared to test structure 128 of FIGS. 1B and 1C. More specifically, test surface 232 of test structure 228 may include a non-planer surface that may include a substantially concave curvature (C2).

As shown in FIG. 2C, and similarly discussed above with respect to FIG. 1C, contact portion 210 of test probe structure 200 may contact test structure 228 during a conductivity testing process. More specifically, contact surface 224 of conductive, conformable component 218 of contact portion 210 may directly contact test surface 232 of test structure 128.

As shown in FIG. 2C, conductive, conformable component 218 may contact test surface 232 and may include a substantially concave curvature that may correspond or compliment concave curvature (C2) of test surface 232. That is, as shown in FIG. 2C, conductive, conformable component 218 may include contact surface 224 that may directly contact test surface 232 and may include a curvature that corresponds to the concave curvature (C2) of test surface 232 when contact portion 210 contacts test structure 228. As similarly discussed above with respect to FIG. 1C, conductive, conformable component 218 may not maintain a uniform thickness when contact portion 210 contacts test structure 228. That is, as shown in FIG. 2C, conductive, conformable component 218 may be substantially compressed when contact portion 210 contacts test structure 228, which may result in a change in thickness of conductive, conformable component 218. More specifically, the thickness of conductive, conformable component 218 at a valley 242 of test surface 232 of test structure 228 may be substantially greater than the thickness of a portion of conductive, conformable component 118 positioned opposite valley 242. As a result of the change in thickness between conductive, conformable component 218, conductive, conformable component 218 may include a second surface 238 coupled to conductive adhesive 220a that may not include a curvature. That is, because conductive, conformable component 218 may be compressed and may include a change in thickness, the orientation of second surface 238 of conductive, conformable component 118 may be substantially unchanged when contact portion 110 of test probe structure contacts test structure 128. Additionally, and as discussed above, because conductive, conformable component 218 is compressed and the orientation of second surface 238 remains substantially unchanged, conductive adhesive 220a may also remain unchanged. That is, the orientation of conductive adhesive 220a may be unchanged, and/or may not include a curvature corresponding or complementing concave curvature (C2) of test surface 232 when contact portion 210 contacts test structure 228.

As similarly discussed above with respect to FIG. 1C, conductive, conformable component 218 of contact portion 210 may form a maximum surface contact with test structure 228. More specifically, conductive, conformable component 218 may contact test surface 232 of test structure 228 and may conform to a complementary curvature of the concave curvature (C2) of test surface 232 to form a maximum surface contact between contact surface 224 of conductive, conformable component 218 and test surface 232 of test structure 228. The maximum surface contact may be substantially seamless and/or may not include any gaps, spaces or openings between conductive, conformable component 118 and test surface 232. That is, the entire contact surface 224 of conductive, conformable component 218 may be in contact with test surface 232 of test structure 228.

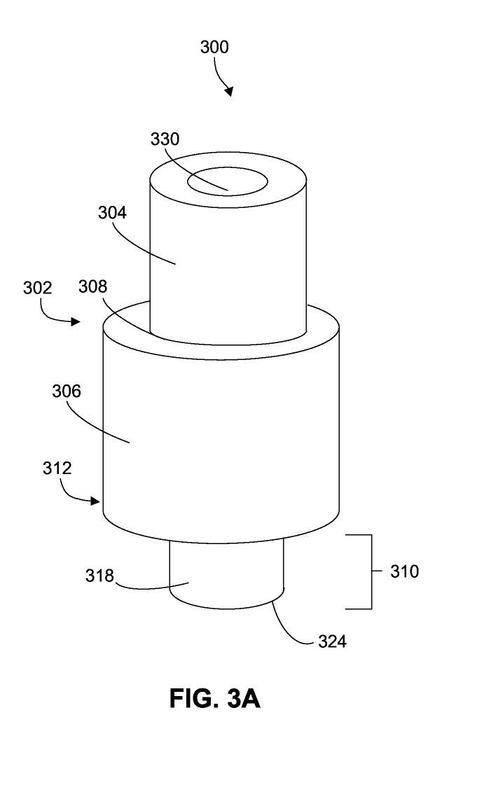

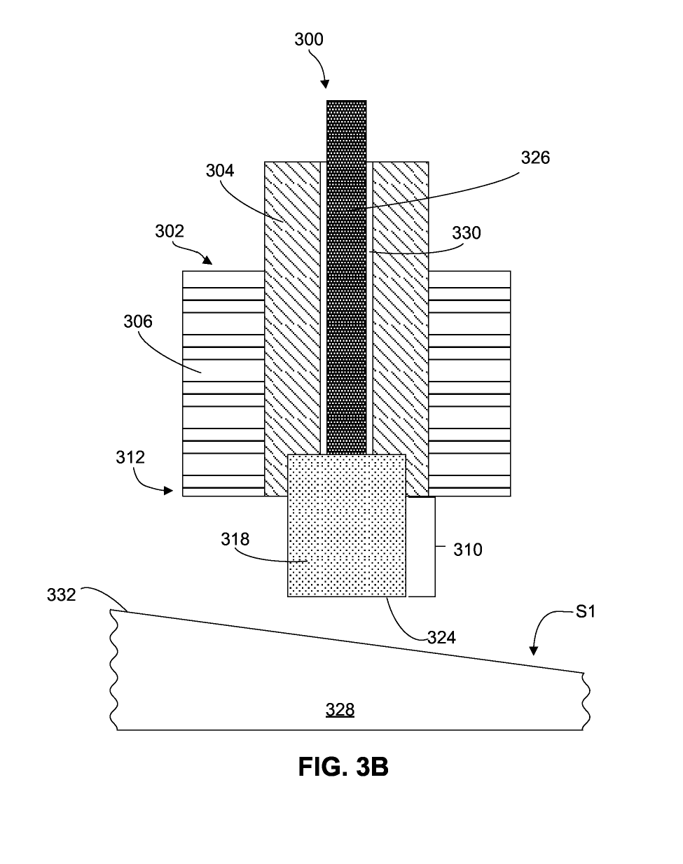

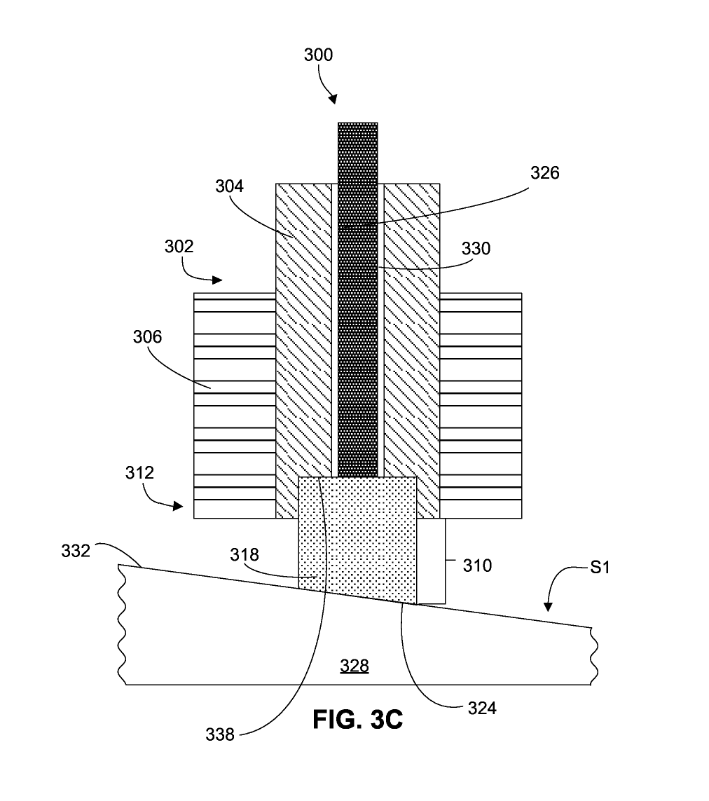

FIGS. 3A-3C shows a perspective and cross-sectional front view, respectively, of test probe structure 300 according to a further embodiment. Test probe structure 300 may include substantially similar components (e.g., probe shaft 104, probe housing 106, etc.) as test probe structure 100. With comparison to FIGS. 1A and 2A, contact portion 310 of test probe structure 300, as shown in FIG. 3A, may only include conductive, conformable component 318. More specifically, as shown in FIGS. 3B and 3C, contact portion 310 may include only conductive, conformable component 318, which may be coupled to, or formed integral with probe support 302. Conductive, conformable component 318 may be coupled to or formed integral with probe support 302, and specifically probe shaft 304, using any conventional coupling technique. In an non-limiting example, conductive, conformable component 318 may be coupled to probe shaft 304 of probe support 302 via a compression fit. As similarly discussed with respect to FIGS. 2A-2C, conductive, conformable component 318 of contact portion 310, as shown in FIGS. 3A-3C, may include contact surface 324. Contact surface 324 may be configured to directly contact test surface 332 of test structure 328 (see, FIGS. 3B and 3C) during a conductivity testing process as discussed herein.

As shown in FIGS. 3B and 3C, test structure 328 may include yet another distinct configuration when compared to test structure 128 of FIGS. 1B and 1C, and/or test structure 228 of FIGS. 2B and 2C. Test structure 328 may include a test surface 332 having a substantially planer surface. More specifically, test surface 332 of test structure 328 may include a planer surface having a uniform angular slope (S1).

As discuss above, and shown in FIG. 3C, contact portion 310 of test probe structure 300 may contact test structure 328 during a conductivity testing process. More specifically, contact surface 324 of conductive, conformable component 318 of contact portion 310 may directly contact test surface 332 of test structure 328. When contacting test structure 328, conductive, conformable component 318 of contact portion 310 may include an substantially similar angular slope as the uniform angular slope (S1) of test surface 332. More specifically, contact surface 324 may contact test surface 332, and conductive, conformable component 318 may compress, such that contact surface 324 includes a substantially similar angular slope as the uniform angular slope (S1) of test surface 332 of test structure 328. As similarly discussed above, conductive, conformable component 318 may not maintain a uniform thickness when contact portion 310 contacts test structure 328 due to the compression of conductive, conformable component 318. As a result of the change in thickness and/or compression of conductive, conformable component 318, a second surface of 338 conductive, conformable component 318, coupled to probe support 302, may not be conformed to include an angle (for example, uniform angular slope (S1)) when conductive, conformable component 318 contacts test structure 328.

In an additional embodiment, as shown in FIGS. 4A-4C contact portion 410 of test probe structure 400 may include a conductive, compression-spring 444 (hereafter, “spring 444”). More specifically, conductive, conformable component, as discussed with respect to FIGS. 1A-3C, may include and/or be replaced by spring 444. Spring 444 may include substantially similar properties and/or characteristics as conductive, conformable component 118, as discussed herein. That is, spring 444 may include an electrically conductive material that may also be substantially flexible or elastic. Spring 444 may be coupled directly to probe shaft 404 of probe support 402 using any conventional coupling technique. In an not limiting example, spring 444 may be welded to probe shaft 404 of probe support 402. As discussed herein, spring 444 may allow contact portion 410 to conform to test surface 432 of test structure 428 (see, FIG. 4B and 4C) when contact portion 410 contacts test structure 428 during a conductivity testing process.

As shown in FIGS. 4A-4C, contact portion 410 of test probe structure 400 may also include conductive element 422 coupled to spring 444. More specifically, conductive element 422 may be coupled to a first end 446 of spring 444 positioned opposite probe support 102 of test probe structure 400. Contact surface 424 of contact portion 410 may include a bottom surface of conductive element 422. In an non-limiting example, conductive element 422 may include a substantially rigid conductive plate that may contact test structure 428. That is, and with comparison to conductive element 122 that may include a flexible conductive film (see, FIGS. 1A-1C), conductive element 422, as shown in FIGS. 4A-4C may include conductive properties, but may not be substantially flexible or elastic. Rather, conductive element 422 may include a rigid conductive plate, and may rely on the flexibility of spring 444 so contact portion 410 may conform or flex to form a maximum surface when contact portion 410 contacts test structure 428, as discussed herein.

As shown in FIGS. 4B and 4C, test structure 428 may include yet another embodiment, distinct from the test structures discussed above. Test structure 428 may include test surface 432 having a substantially planer surface, as similarly discussed with respect to test surface 332 in FIGS. 3B and 3C. However, and in comparison to test structure 328 in FIG. 3B and 3C, test surface 432 may include a planer surface having a distinct uniform angular slope (S2). More specifically, directional pitch of test surface 432 including uniform angular slope (S2) may be distinction from the angular slope (S1) of test surface 332, as shown in FIG. 3B and 3C.

As shown in FIG. 4C, conductive element 422 of test probe structure 400 may contact test structure 428 during a conductivity testing process, as discussed herein. More specifically, contact surface 424 of conductive element 422 may contact test surface 432 of test structure 428, and conductive element 422 may include a substantially similar angular slope as uniform angular slope (S2) of test surface 432. As shown in FIG. 4C, and compared with FIG. 4B, conductive element 422, including substantially rigid plate, may maintain a uniform thickness when conductive element 422 contacts test surface 432. That is, because of conductive element's 422 rigid, or substantially inelastic properties, conductive element 422 may not be compressed when contacting test surface 432 of test structure 428. Rather, conductive element 422 may be substantially displaced (for example, rotated) to include an angular slope similar to the uniform angular slope (S2) of test surface 432. Conductive element 422 may be displaced as a result of the compression and/or displacement of spring 444 of contact portion 410. More specifically, because of the elastic or flexible characteristics of spring 444, spring 444 may be substantially compressed, and may also be laterally displaced when conductive element 422 of test probe structure 400 contacts test structure 428. As shown in FIG. 4C, spring 444 may be compressed to include a reduced length, and may also include a plurality of displaced spring coils that may not be in vertical alignment with the remainder of the spring coils of spring 444. The compressed, vertically-misaligned coils may allow conductive element 422 to be displaced to align with and/or include an angular slop similar to the uniform angular slope (S2) of test surface 432.

Although conductive element 422 may be substantially rigid, contact portion 410 of test probe structure 400 may form a maximum surface contact between conductive element 422 and test surface 432. More specifically, as a result of the flexible or elastic characteristics of spring 444, conductive element 422 of contact portion 410 may contact test surface 432 and include a substantially similar angular slope as uniform angular slope (S2) of test surface 432, in order to form a maximum surface contact between conductive element 422 and test surface 432. The maximum surface contact may be substantially seamless and/or may not include any gaps, spaces or openings between conductive, conductive element 422 and test surface 432. That is, the entire contact surface 424 of conductive element 422 may be in contact with test surface 432 of test structure 428 as a result of spring 444 ability to compress and/or be laterally displaced.

In an alternative embodiment, as shown in FIG. 4D, spring 444 may be integral with probe support 402. More specifically, spring 444 may be formed from a portion of probe shaft 104 of probe support 402. Where probe support 402 includes an integral spring 444, probe shaft 404 may include a spring portion 448 and a bottom portion 450 for coupling probe shaft 404 of probe support 402 to conductive element 422. As shown in FIG. 4D, spring 444 may be formed by machining a portion probe shaft 404, such that probe shaft of probe support 402 may be substantially compressed and/or laterally displaced when conductive element 422 of test probe structure 400 contacts test surface 432 of test structure 428 during a conductivity testing process, as discussed herein. Forming spring 444 directly within or integral to probe support 402 may allow probe support 402 to provide an additional force on contact portion 410 to substantially ensure a maximum contact surface between contact portion 410 and test surface 432 when contact portion 410 contacts test structure 428.

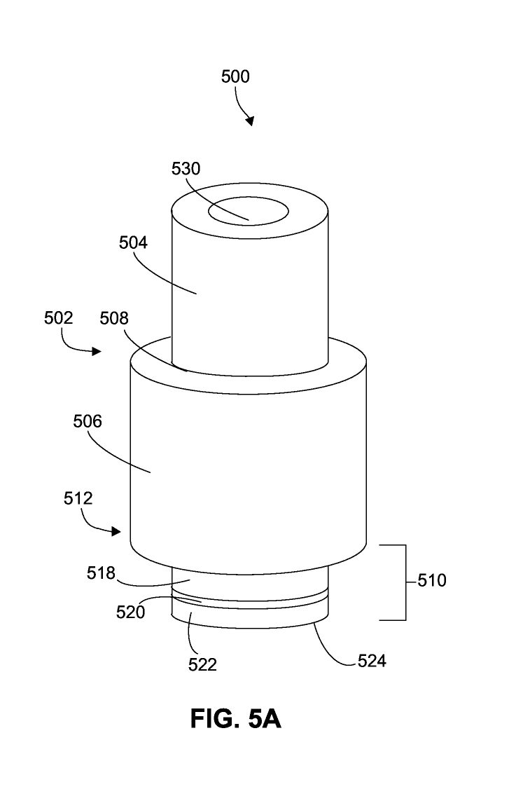

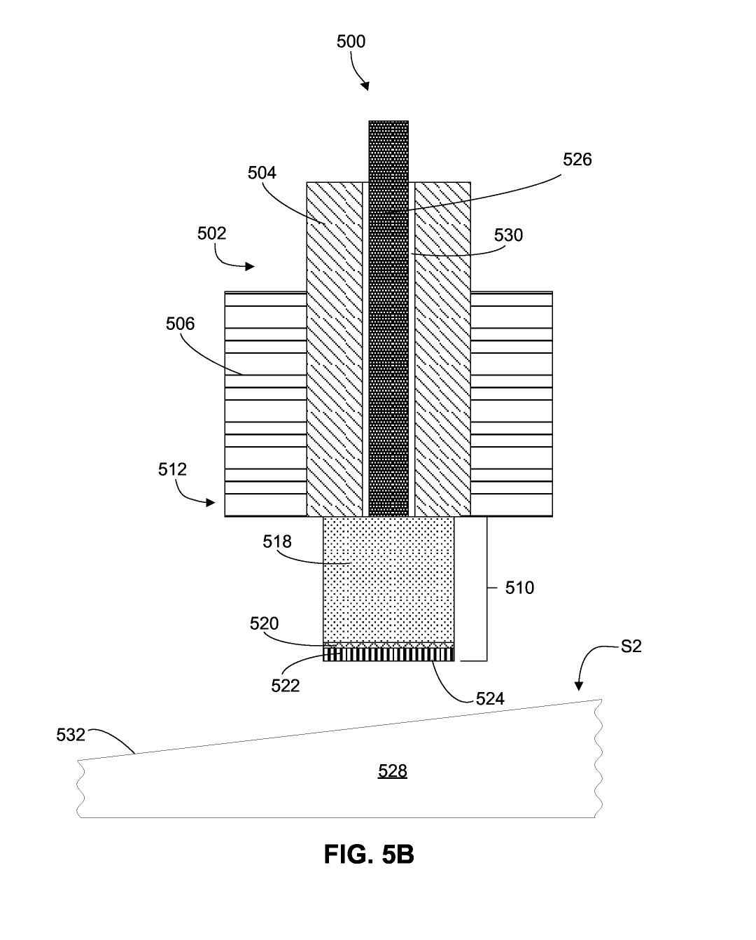

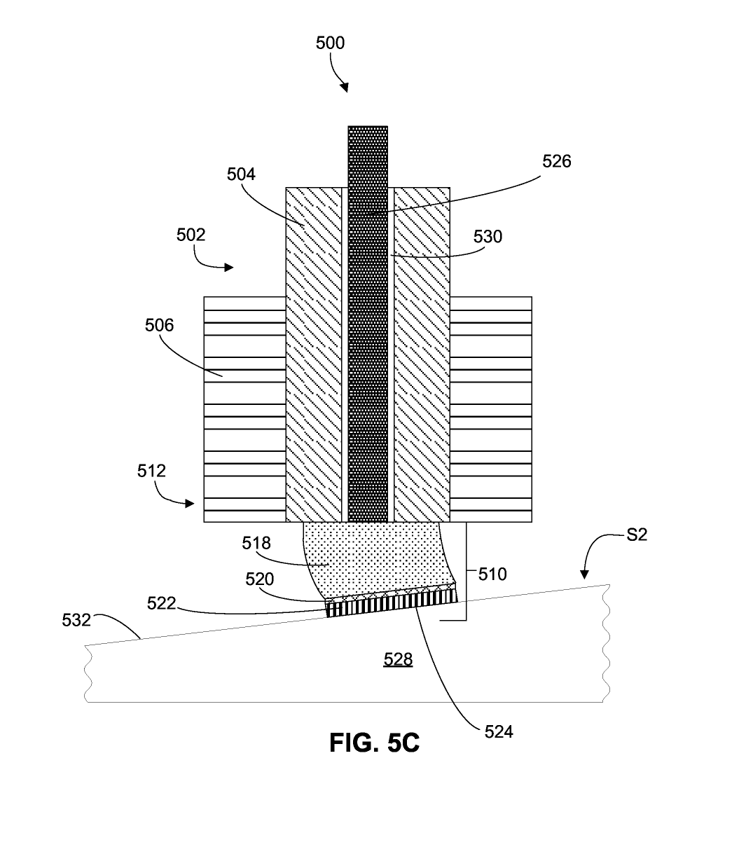

FIG. 5A shows a perspective view of test probe structure 500, according to another embodiment. Test probe structure 500 may include an alternative embodiment of contact portion 510. More specifically, and with reference to FIGS. 5B and 5C, contact portion 510 of test probe structure 500 may include conductive, conformable component 518 coupled directly to probe shaft 504 of probe support 502, and a conductive element 522 coupled to conductive, conformable component 518. Conductive element 522 may be coupled to conductive, conformable component 518 using a conductive adhesive 520. As shown in FIGS. 5A-5C, and as similarly discussed with respect to conductive element 422 in FIGS. 4A-4D, conductive element 522 may be substantially rigid or inelastic. Conductive element 522 may include contact surface 524 configured to contact test structure 528 during a conductivity testing process, as discussed herein.

Turning to FIGS. 5B and 5C, test structure 528 may include a substantially similar configuration to test structure 428 of FIGS. 4B and 4C. More specifically, test structure 528 may include test surface 532, which may include a planer, uniform angular slope (S2). Also similar to FIG. 4C, conductive element 522 of contact portion 510 may contact test surface 532 and may include a substantially similar angular slope as uniform angular slope (S2) of test surface 532, while also maintaining a uniform thickness (for example, no compression). As shown in FIG. 5C, conductive, conformable component 518 may be substantially compressed and/or laterally displaced when conductive element 522 of contact portion 510 contacts test surface 532. That is, and as discussed herein, conductive, conformable component 518 may be substantially flexible or elastic and may be compressed when contact portion 510 contacts test surface 532. In addition, and similarly discussed above with respect to spring 444 in FIG. 4C, conductive, conformable component 518 may also be laterally displaced when contact portion 510 contacts test surface 532. As a result of conductive, conformable component 518 ability to be compressed and/or laterally displaced, conductive element 522, including a substantially rigid conductive plate, may be displaced (for example, rotated) to include an angular slope similar to the uniform angular slope (S2) of test surface 532 of test structure 528.

FIG. 6 shows a perspective view of a test probe system 660 including a test probe structure 600 and a test structure 628 according to embodiments. Test probe structure 600 of test probe system 660 may include substantially similar components (e.g., probe shaft, conductive, conformable component, conductive element, etc.) as the test probe structures discussed herein with respect to FIGS. 1A-5C. It is understood that similarly named components or similarly numbered components may function in a substantially similar fashion, may include similar materials and/or may include similar interactions with other components. Redundant explanation of these components has been omitted for clarity.

As shown in FIG. 6, test probe structure 600 of test probe system 660 may include a probe support 602 coupled to a movable armature 662. Armature 662 of test probe system 660 may be configured to move test probe structure 600 during a conductivity testing process, as discussed herein. More specifically, armature 662 may be coupled to probe support 602 of test probe structure 600, and may be configured to move test probe structure 600 to be positioned above a test surface 632 of test structure 628 and/or may be configured to move test probe structure 600 to contact test structure 628 during a conductivity testing process. Armature 662 of test probe system 660 may include any conventional configuration or system capable of moving and/or positioning test probe structure 600 within test probe system 660. In an non-limiting example, armature 662 may include a track carrier 664 coupled to a track system (not shown) that may move or position test probe structure 600 over a test surface 632 of test structure 628, and a telescoping shaft 668 coupled to track carrier 664 that may adjust test probe structure 600 to contact test surface 632 of test structure 628.

Probe support 602 of test probe structure 600 may include a probe shaft 604 including a conductive, compression-spring 644, as similarly discussed herein with respect to FIG. 4D. More specifically, as shown in FIG. 6, probe support 602 may include a probe shaft 604 including an integral conductive, compression-spring 644 formed within probe support 602. As discussed herein, conductive, compression-spring 644 may provide an additional force on contact portion 610 when contact portion 610 is in contact with test structure 628. However, it is understood that probe support 602 may include a variety of components discussed above. In a non-limiting example, probe support 602 may include a solid probe shaft 604, as similarly discussed with respect to FIGS. 1A-1C. As discussed herein, probe support 602 may provide support to contact portion 610 and it various layers or components, and/or may ensure contact portion 610 is provided with enough pressure to form a maximum surface contact between contact portion 610 of test probe structure 600 and test surface 632 of test structure 628.

As shown in FIG. 6, contact portion 610 may be coupled to probe support 602, opposite armature 662 of test probe system 660. That is, contact portion 610 may be coupled to probe shaft 604 of probe support 602, and positioned adjacent test surface 632 of test structure 628. Contact portion 610 of FIG. 6 may be substantially similar to contact portion 510 of FIGS. 5A-5C. That is, contact portion 610 of test probe structure 600 may include conductive, conformable component 618 coupled to probe support 602 and conductive element 622 coupled to conductive, conformable component 618 via conductive adhesive 620. Conductive element 622 may include contact surface 624 positioned adjacent test structure 628.

Test probe system 660 may also include a conductive liquid dispensing system 670 (hereafter, “CLD system 670”) positioned adjacent test probe structure 600. As discussed herein, CLD system 670 may be configured to supply a conductive liquid 672 to test surface 632 of test structure 628 during a conductivity testing process. As shown in FIG. 6, CLD system 670 may include a mounting member 674 coupled to track carrier 664 of armature 662. Mounting member 674 may be coupled to track carrier 664 to provide a housing for a dispensing conduit 676 of CLD system 670 that may supply conductive liquid 672 to test structure 628. More specifically, dispensing conduit 676 may be positioned within mounting member 674 coupled to track carrier 664 of test probe system 660, and may include a first end 678 positioned adjacent conductive, conformable component 618 of test probe structure 600 and test surface 632 of test structure 628, respectively. Dispensing conduit 676 of CLD system 670 may supply the conductive liquid 672 to test surface 632 of test structure 628 via first end 678. Dispensing conduit 676 may include any conventional conduit capable of carrying and/or dispensing conductive liquid 672, where conductive liquid include alcohol. As discussed herein, conductive liquid 672 may form an electrically conductive, intermediate layer between test probe structure 600 and test structure 628 to ensure a maximum surface contact between contact portion 610 of test probe structure 600 and test surface 632 of test structure 628.

As a result of mounting member 674 being coupled to track carrier 664 of test probe system 660, dispensing conduit 676 may move freely with test probe structure 600 when track carrier 664 positions test probe structure 600 over test surface 632 of test structure 628. This may substantially ensure that dispensing conduit 676 of CLD system 670 may dispense conductive liquid 672 over test surface 632 during a conductivity testing process, as discussed herein. However, because mounting member 674 is coupled to track carrier 664, dispensing conduit 676 may remain substantially stationary, and positioned a fixed distance above test surface 632 when telescoping shaft 668 of test probe system 660 positions test probe structure 600 to contact test structure 628.

In an alternative embodiment (not shown), mounting member 674 may be coupled directly to probe support 602 (for example, probe shaft 604). Where mounting member 674 is coupled to probe support 602 of test probe structure 600, dispensing conduit 676 of CLD system 670 may move with test probe structure 600 based on the movements initiated by track carrier 664 and telescoping shaft 668. That is, similar to FIG. 6, dispensing conduit 676 may move freely with test probe structure 600 when track carrier 664 positions test probe structure 600 over test surface 632 of test structure 628. In addition, dispensing conduit 676 may move toward test surface 632 with test probe structure 600 when telescoping shaft 668 positions contact portion 610 of test probe structure 600 in contact with test surface 632 of test structure 628.

As shown in FIG. 6, dispensing conduit 676 of CLD system 670 may be in fluid communication with a conductive liquid reservoir 680. More specifically, CLD system 670 may include conductive liquid reservoir 680 in fluid communication with dispensing conduit 676, and configured to store conductive liquid 672 and/or provide dispensing conduit 676 with conductive liquid 672 to be supplied to test structure 628. Conductive liquid reservoir 680 may include any convention storage device or liquid supply system that may substantially contain, hold and/or provide conductive liquid 672. In non-limiting examples, conductive liquid reservoir 680 may include a storage tank, or a supply line in fluid communication with dispensing conduit 676 and an auxiliary storage device (not shown) including conductive liquid 672.

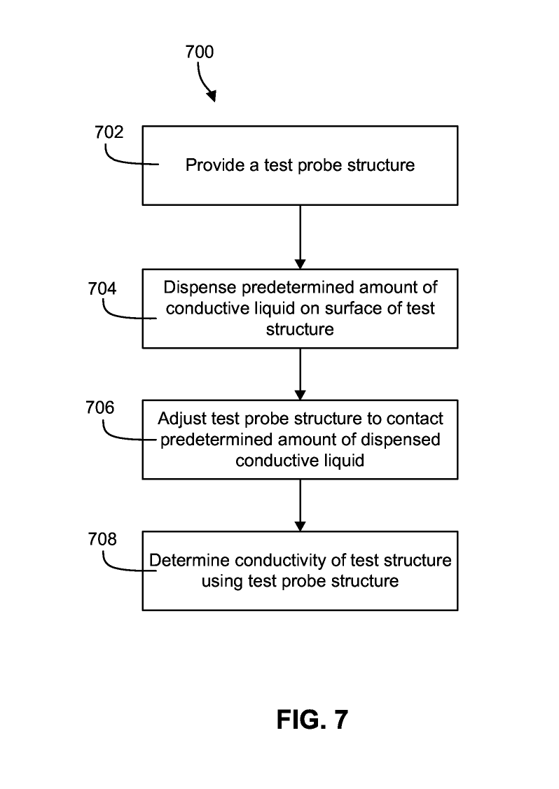

Turning to FIG. 7, a method for testing conductivity of a test structure 128 (see, FIGS. 1B and 1C) is now discussed. Specifically, FIG. 7 is a flowchart depicting one sample method 700 for testing the conductivity of a test structure, as discussed herein with respect to FIGS. 1C-5C.

In operation 702, a test probe structure may be proved. More specifically, a test probe system including a test probe structure may be provided. The test probe structure may include a conductive, conformable component configured to directly contact a test surface of the test structure, or may couple a conductive element of the test probe structure to a probe support of the test probe structure. In an embodiment where the test probe structure includes the conductive element, the conductive element may directly contact the test surface of the test structure, as discussed herein. The test probe structure provided may include any of the test probe structures discussed herein with respect to FIGS. 1A-5C.

In operation 704, an amount of conductive liquid may be dispensed on the test surface of the test structure. The conductive liquid dispensed on the test surface of the test structure may be provided by a conductive liquid dispensing system of the test probe system. More specifically, the conductive liquid dispensing system of the test probe system may dispense a predetermined amount of conductive liquid on a portion of the test surface of the test structure positioned adjacent to and/or in alignment with the test probe structure. As discussed herein, the conductive liquid may form an electrically conductive, intermediate layer between the test probe structure and the test structure to ensure a maximum surface contact between the test probe structure and the test surface of the test structure.

In operation 706, the test probe structure may be adjusted to contact the conductive liquid and/or the test structure. More specifically, the test probe system may move the test probe structure toward the test structure, such that the test probe structure may contact at least one of the conductive liquid dispensed on the test surface of the test structure and/or the test surface of the test structure. The test probe structure may contact the conductive liquid and/or the test structure dependent upon a variety of factors including, but not limited to: the shape or configuration of the test surface of the test structure, the amount of conductive liquid dispensed on the test surface, the dimensions of the conductive, conformable component, the dimensions of the conductive element, and the positioning of the test probe structure relative to the test surface of the test structure.

Once the test probe structure is adjusted in operation 706, subsequent processes may occur. More specifically, subsequent to the adjusting of the test probe structure in operation 706, a portion of the conductive liquid dispensed on the test surface may be displaced. That is, when test probe structure is adjusted to contact the conductive liquid, a portion of the conductive liquid positioned between the test probe structure and the test surface of the test structure may be substantially displaced to a portion of the test surface uncovered or positioned adjacent the test probe structure. In response to the displacing of the portion of the conductive liquid, a thin layer of the conductive liquid may be formed between the test probe structure and the test surface of the test structure. More specifically, the remaining portion of the conductive liquid that is not displaced after the adjusting of the test probe structure may form a thin layer of conductive liquid that may be positioned between and/or may contact both the test probe structure and the test surface of the test structure. As such, the forming of the thin layer of the conductive liquid may also include flowing a portion of the conductive liquid positioned between the test probe structure and the test structure to a section of the surface uncontacted by the test probe structure or a section of the surface aligned with the test probe structure, that may be uncovered by the conductive liquid.

By displacing a portion of the conductive liquid positioned between the adjusted test probe structure and test surface, and forming the thin layer of conductive liquid, a seamless contact between test probe structure and the test surface of the test structure may be created. More specifically, the thin layer formed between the test probe structure and the test structure may create a maximum surface contact or seamless contact between the test probe structure and the test surface of the test structure, where the test probe structure is in complete contact with the test surface of the test structure by direct contact, or indirect contact via the conductive liquid.

In operation 708, the conductivity of the test structure may be determined using the test probe structure. More specifically, the electrical conductivity of the test structure may be determined using the test probe structure in contact with the conductive liquid and/or the test surface of the test structure. The conductivity of the test structure may be determined using the test probe structure of the test probe system and any conventional conductivity measuring device and/or system. In a non-limiting example, where the conductive, conformable component of the test probe structure contacts the conductive liquid and/or the test surface, a measuring device in electronic communication with the conductive, conformable component may transmit a test electrical current to the test structure to determine the conductivity of the test structure. Specifically, the measuring device may transmit the test current to the test structure via the conductive, conformable component, and may monitor or detect a return current received by the conductive, conformable component after the test current is passed through the test structure.

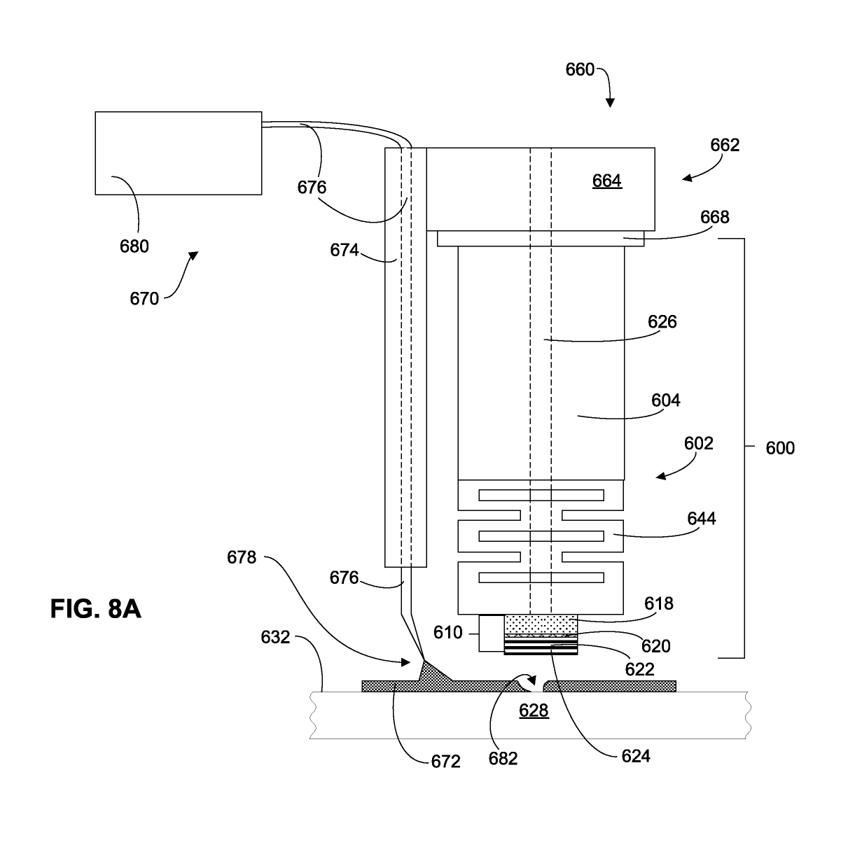

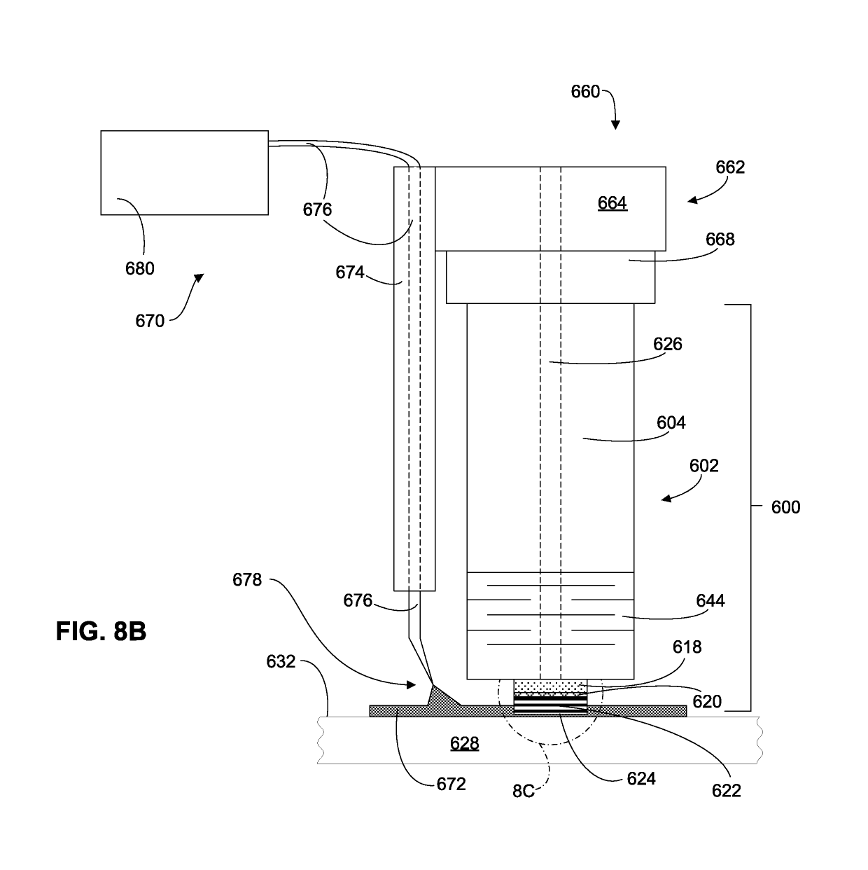

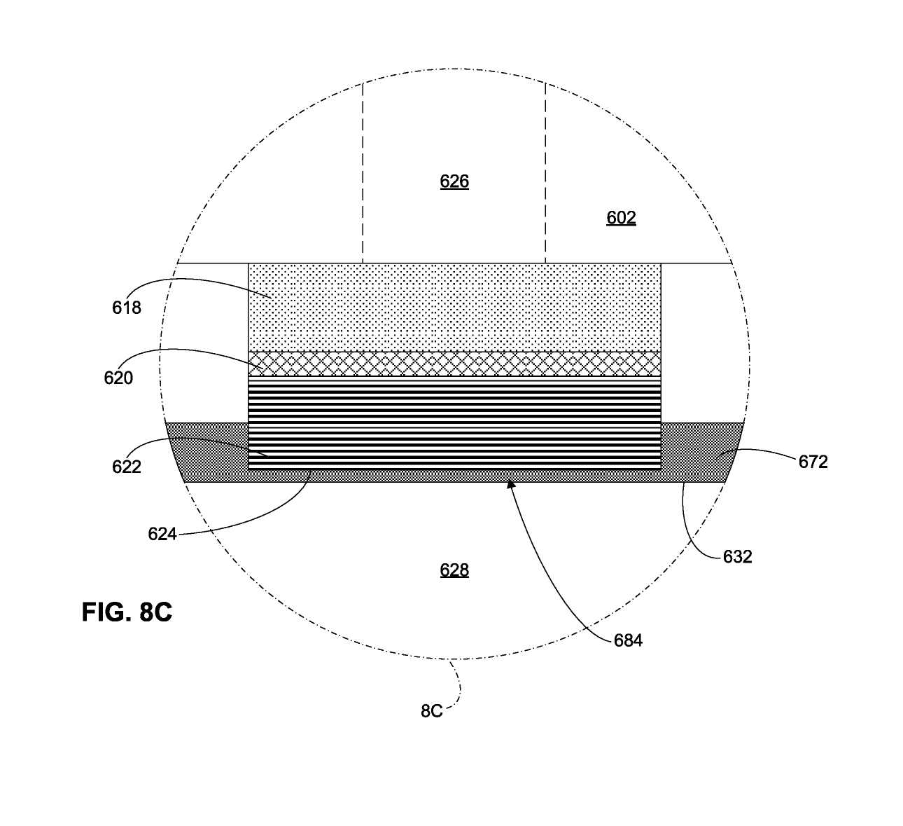

Turning to FIGS. 8A-8C, a sample test probe system 600 undergoing various operations of method 700 of FIG. 7 may be depicted. Test probe system 600 of FIGS. 8A-9 may be substantially similar to test probe system 600 of FIG. 6. It is understood that similarly numbered components may function in a substantially similar fashion. Redundant explanation of these components has been omitted for clarity.

FIG. 8A shows test probe system 660 including test probe structure 600 and conductive liquid dispensing system 670 (hereafter, “CLD system 670”) according to embodiments. Test probe system 660, and specifically test probe structure 600, may be provided to be positioned substantially above test surface 632 of test structure 628. Test probe system 660 including test probe structure 600, as shown in FIG. 8A, may correspond to operation 702 of FIG. 7. As shown in FIG. 8A, and as similarly discussed with respect to FIG. 6, test probe structure 600 may include a probe support 602 including a probe shaft 604 and a conductive, compression-spring 644 formed integral with the probe shaft 604. Additionally, test probe structure 600 may include a contact portion 610. Contact portion 610 may include conductive, conformable component 618 coupled to probe support 602, and conductive element 622 coupled to conductive, conformable component 618 via conductive adhesive 620. As shown in FIG. 8A, and discussed above, conductive element 622 may include a contact surface 624 positioned adjacent to test surface 632 of test structure 628.

As shown in FIG. 8A, conductive liquid 672 may be dispensed onto test surface 632 of test structure 628. More specifically, CLD system 670 may dispense conductive liquid 672 on test surface 632 of test structure 628 via dispensing conduit 676. As discussed herein with respect to FIG. 6, the conductive liquid 672 may be dispended from first end 678 of dispensing conduit 676, which may be in fluid communication with a conductive liquid reservoir 680. The dispensed conductive liquid 672 on test surface 632 of test structure 628, as shown in FIG. 8A, may correspond to operation 704 of FIG. 7.

The dispensed conductive liquid 672 on test surface 632 may not cover all of the intended portion of test surface 632. That is, as shown in FIG. 8A, test surface 632 may include an uncovered portion 682, that may be formed from a break or separation in the dispensed conductive liquid 672. The uncovered portion 682 may be positioned underneath and in alignment with contact portion 610 of test probe structure 600. Uncovered portion 682 may be formed from non-uniformity in the dispensing of conductive liquid 672. More specifically, uncovered portion 682 of test surface 632 may be formed where conductive liquid 672 is dispensed onto test surface 632 but separates and/or is not a cohesive liquid.

As shown in FIG. 8B, test probe structure 600 may be moved toward test structure 628 in order for contact portion 610 to contact conductive liquid 672 and/or test surface 632 of test structure 628. More specifically, contact surface 624 of conductive element 622 may contact conductive liquid 672 and/or test surface 632 as a result of telescoping scoping shaft 668 of armature 662 of test probe system 600 extending test probe structure 600 toward test structure 628. Test probe structure 600, and specifically conductive element of contact portion 610, contacting test surface 632 of test structure 628, as shown in FIG. 8B, may correspond to operation 706 of FIG. 7. As shown in FIG. 8B, and similarly discussed herein, conductive, compression-spring 644 may be substantially compressed to ensure contact surface 624 of conductive element 622 completely contacts conductive liquid 672 and/or test surface 632 of test structure 628.

Additionally, the positioning of test probe structure 600 to contact conductive liquid 672 and/or test surface 632 of test structure 628 may eliminate uncovered portion 682 of test surface 632. More specifically, as shown in FIGS. 8B and 8C, the adjusting of the position of test probe structure 600 by telescoping shaft 668 of test probe system 660 may result in a portion of conductive liquid 672 to be displaced from underneath contact portion 610 to areas of test surface 632 positioned adjacent contact portion 610. This displacing may ultimately result in the formation of a thin, continuous layer 684 of conductive liquid 672 positioned adjacent to and between contact surface 624 of conductive element 622 and test surface 632 of test structure 628. That is, the displacing and/or formation may cause a portion of conductive liquid 672 to flow to and substantially cover uncovered portion 682 of test surface 632. As a result, thin layer 684 of conductive liquid 672 may allow conductive element 622 of contact portion 610 to be in complete electrical communication with test structure 628. That is, as shown in FIGS. 8B and 8C, the entire contact surface 624 of conductive element 622 of test probe structure 600 may be covered by and/or contact conductive liquid 672, which may also be in contact with a portion of test surface 632 of test structure 628 positioned in alignment with contact portion 610. As a result of the entire contact surface 624 of conductive element 622 being covered by and/or in contact with conductive liquid 672 and ultimately test surface 632, during the determining of the conductivity of test structure 628, as discussed above with reference to operation 708 in FIG. 7, the determined conductivity may be substantially accurate and/or free from error as a result of inadequate contact between test probe structure 600 and test structure 628.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of the specific embodiments described herein are presented for purposes of illustration and description. They are not target to be exhaustive or to limit the embodiments to the precise forms disclosed. It will be apparent to one of ordinary skill in the art that many modifications and variations are possible in view of the above teachings.

We claim:

1. A test probe structure comprising:
a probe support; and
a conductive, conformable component coupled to the probe support, the conductive, conformable component configured to:
directly contact a test surface of a test structure, or
couple a conductive element to the probe support, wherein the conductive element directly contacts the test surface of the test structure.

2. The test probe structure of claim 1, wherein the probe support includes a conductive metal.

3. The test probe structure of claim 1, wherein the conductive, conformable component includes at least one of:
a conductive foam,
a conductive polymer, and
a conductive fabric material.

4. The test probe structure of claim 1, wherein the conductive, conformable component includes a conductive compression-spring.

5. The test probe structure of claim 4, wherein the conductive compression-spring is integral with the probe support.

6. The test probe structure of claim 1, further comprising a conductive adhesive positioned between the conductive, conformable component and the probe support,
wherein the conductive adhesive is configured to couple the conductive, conformable component to the probe support.

7. The test probe structure of claim 4 wherein the conductive adhesive is positioned between the conductive, conformable component and the conductive element,
wherein the conductive adhesive is configured to couple the conductive element to the conductive, conformable component.

8. The test probe structure of claim 1, wherein the conductive element coupled to the probe support includes at least one of:
a substantially flexible conductive film, or
a substantially rigid conductive plate.

9. The test probe structure of claim 1, wherein one of the conductive, conformable component or the conductive element contacts a conductive liquid positioned on the test surface of the test structure.

10. A test probe system comprising:
a test probe structure including:
a probe support; and
a conductive, conformable component coupled to the probe support, the conductive, conformable component configured to:
directly contact a test surface of a test structure, or
couple a conductive element to the probe support,
wherein the conductive element directly contacts the test surface of the test structure; and
a conductive liquid dispensing system positioned adjacent to the test probe structure, the conductive liquid dispensing system configured to supply a conductive liquid to the test surface of the test structure.

11. The test probe system of claim 10, wherein the conductive liquid dispensing system includes a dispensing conduit having a first end positioned adjacent the conductive, conformable component and the test surface of the test structure,
wherein the dispensing conduit supplies the conductive liquid to the test surface of the test structure via the first end.

12. The test probe system of claim 11, wherein the conductive liquid dispensing system further includes a conductive liquid reservoir in fluid communication within the dispensing conduit.

13. The test probe system of claim 10, wherein the conductive liquid includes alcohol.

14. The test probe system of claim 10, wherein the probe support includes a conductive, compression-spring portion.

15. The test probe system of claim 14, wherein the conductive, compression-spring portion is integral with the probe support.

16. The test probe system of claim 14, wherein the conductive, conformable component is coupled to the conductive, compression-spring portion of the probe support.

17. A method for testing electrical conductivity of a structure, the method comprising:
providing a test probe structure including:
a conductive, conformable component configured to:
directly contact a surface of the structure, or
couple a conductive element to a probe support of the test probe structure,
wherein the conductive element directly contacts the surface of the structure;
dispensing a conductive liquid on the surface of the structure;
adjusting the test probe structure to contact at least one of:
the conductive liquid dispensed on the surface of the structure, and
the surface of the structure; and
determining the conductivity of the structure using the test probe structure in contact with at least one of:
the conductive liquid dispensed on the surface of the structure, and
the surface of the structure.

18. The method of claim 17, further comprising:
displacing a portion of the conductive liquid dispensed on the surface of the structure in response to the adjusting of the test probe structure to contact the conductive liquid;
forming a thin layer of the conductive liquid between the test probe structure and the surface of the structure; and
creating a seamless contact between the test probe structure and the surface of the structure via the formed thin layer of the conductive liquid.

19. The method of claim 18, wherein the creating of the seamless contact includes flowing a portion of the conductive liquid to one of:
a section of the surface uncontacted by the test probe structure, or
a section of the surface aligned with the test probe structure, and uncovered by the conductive liquid.

20. The method of claim 17, wherein the dispensing of the conductive liquid on the surface of the structure further comprises dispensing electrically conductive alcohol on a portion of the surface in alignment with the test probe structure.
